(19) United States
(12) Patent Application Publication
(10) Pub. No.: US 2012/0206789 A1
(43) Pub. Date: Aug. 16, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); JIA HUANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/166,323

(22) Filed: Jun. 22, 2011

(30) Foreign Application Priority Data
Feb. 15, 2011 (CN) 201110038484.5

(51) Int. Cl. G02F 1/15; C23C 14/34; B32B 5/00

(52) U.S. Cl. 359/265; 428/336; 428/457; 252/583; 204/192.15

(57) ABSTRACT

A coated article includes an electrochromic layer made of tungsten trioxide doped with metal selected from molybdenum, niobium, and/or titanium. A method for making the device housing is also described there.

### BACKGROUND

1. Technical Field

The present disclosure relates to coated articles, particularly to a coated article having an electrochromic property and a method for making the coated article.

2. Description of Related Art

Electrochromic materials undergo a reversible change of color or transparency under the application of an externally generated voltage or electric field. Devices incorporating these materials have been widely utilized in the construction of mirrors, displays, and windows for example. These electrochromic materials are commonly made of organic electrochromic material. However, the organic electrochromic material has a low reversibility, and a short lifetime.

Therefore, there is room for improvement within the art.

### BRIEF DESCRIPTION OF THE FIGURE

Many aspects of the coated article can be better understood with reference to the following figures. The components in the figures are not necessarily drawn to scale, the emphasis instead being placed upon clearly illustrating the principles of the coated article.

FIG. 1 illustrates a cross-sectional view of an exemplary embodiment of a coated article.

FIG. 2 is a schematic view of a magnetron sputtering coating machine for manufacturing the article in FIG. 1.

### DETAILED DESCRIPTION

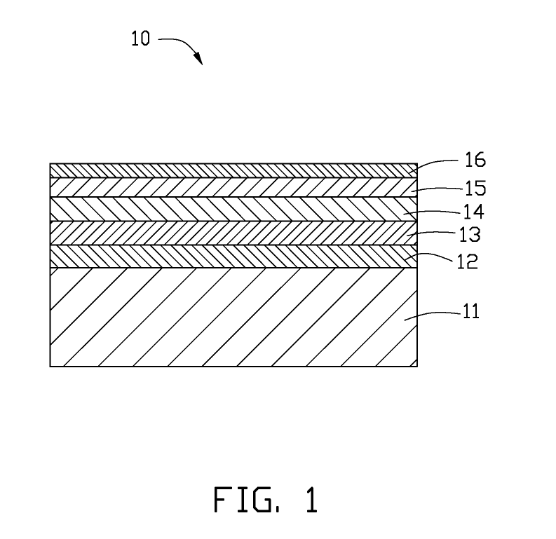

FIG. 1 shows a coated article 10 according to an exemplary embodiment. The coated article 10 includes a substrate 11, a first conductive layer 12, an electrochromic layer 13, an ion conductor layer 14, an ion storage layer 15 and a second conductive layer 16. The first conductive layer 12 and the second conductive layer 16 are used for applying electric field to the coated article 10. The ion conductor layer 14 and the ion storage layer 15 provide electrons or ions for the electrochromic layer 13 under the electric field. The electrons or ions allow the electrochromic layer 13 to have redox reaction for changing color.

The substrate 11 may be made of metal or non-metal material. The metal may be selected from a group consisting of stainless steel, aluminum alloy, and magnesium alloy. The non-metal material may be glass, plastic or ceramic.

The first conductive layer 12 is located on the substrate 11. In this exemplary embodiment, the first conductive layer 12 is transparent and is made of indium-tin-oxide (ITO) or aluminium zinc oxide (AlZO). The first conductive layer 12 can be provided by conventional deposition techniques, such as sputtering deposition or vapor evaporation. It is to be understood that other deposition methods of providing the first conductive layer 12 can also be employed.

The electrochromic layer 13 is made of tungsten trioxide (WO₃) doped with A metal, wherein A may be selected from a group consisting of one or more of molybdenum (Mo), niobium (Nb), and titanium (Ti). In this exemplary embodiment, the A metal has an atomic percentage in a range from about 4% to 12% in the electrochromic layer 13. The electrochromic layer 13 has a thickness of about 500 nm to about 800 nm. The voltage needed for changing the color of the electrochromic layer 13 is in a range from about 2.1 V to about 2.8 V. The electrochromic layer 13 is formed by sputtering deposition. Since the atomic diameter of A metal is similar to the atomic diameter of tungsten the A metal will inhibit the growth of the WO₃ grains during forming the electrochromic layer 13. This allows WO₃ grains to remain refined and increases the flow of ions. In addition, the presence of A metal may eliminate some of the W—O—W bonds. This will help migrate ions in and out of the electrochromic layer 13, and reduce the voltage needed to change color.

The ion conductor layer 14 is located on the electrochromic layer 13. The ion conductor layer 14 is capable of reversibly transporting positive metal ions into and out of the electrochromic layer 13. In this embodiment, the ion conductor layer 14 is formed from LiTaO₃ or LiNbO₃ by sol-gel process.

The ion storage layer 15 is located on the ion conductor layer 14. In this embodiment, the ion storage layer 15 is formed from vanadium pentoxide (V₂O₅) or nickel oxide (NiOₓ) by sol-gel process or sputtering deposition.

The second conductive layer 16 is located on the ion storage layer 15. The composite of the second conductive layer 16 is similar to the first conductive layer 12. In this exemplary embodiment, the second conductive layer 16 is transparent, and is made of indium-tin-oxide (ITO) or aluminium zinc oxide (ALZO).

A method for making the coated article 10 in an embodiment may include the following steps:

The substrate 11 is pretreated. The pre-treating process may include the following steps:

The substrate 11 is cleaned in an ultrasonic cleaning device (not shown), which is filled with ethanol or acetone. The cleaning time is about 5 minutes to about 10 minutes.

The substrate 11 is plasma cleaned. The substrate 11 may be positioned in a plating chamber. The plating chamber is then evacuated to about 3.0×10⁻³ Pa to about 5.0×10⁻³ Pa. Argon (Ar) may be used as a working gas and be injected into the chamber at a rate from about 200 standard cubic centimeter per minute (sccm) to about 400 sccm. The substrate 11 may have a voltage in a range of −200 V to about −300 V, then high-frequency voltage is produced in the plating chamber and the Ar is ionized to the plasma. The plasma then strikes the surface of the substrate 11 to clean the surface of the substrate 11. Plasma cleaning the substrate 11 may take about 10 minutes to about 20 minutes. The plasma cleaning process allows the substrate 11 to form a coarse or rugged surface for enhancing the bond between the substrate 11 and the layer on the substrate 11.

The first conductive layer 12 is formed on the pretreated substrate 11 by conventional deposition techniques. In this exemplary embodiment, the first conductive layer 12 is made of indium-tin-oxide (ITO) or aluminium zinc oxide (ALZO).

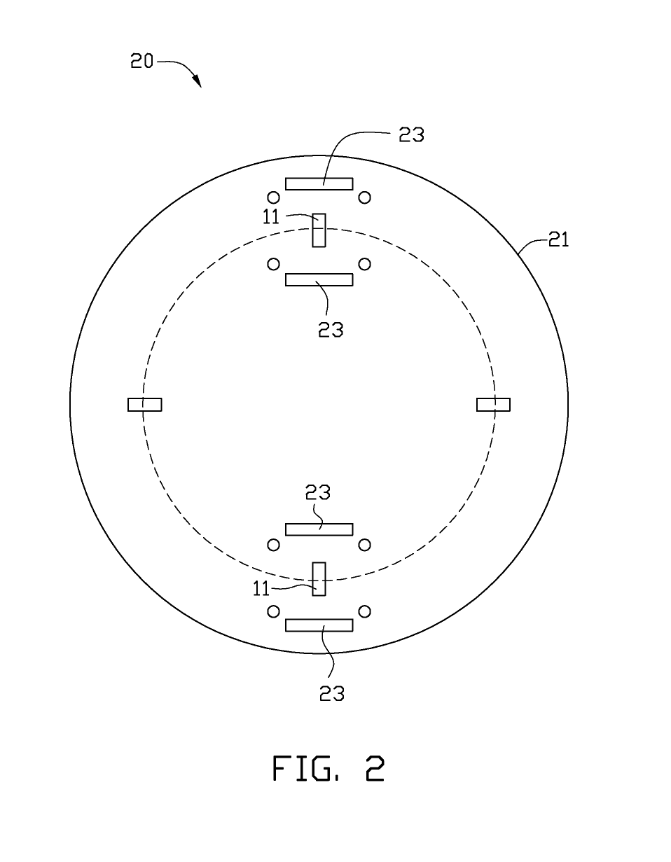

The electrochromic layer 13 is vacuum sputtered on the first conductive layer 12 of the substrate 11. Referring to FIG. 2, the substrate 11 with the first conductive layer 12 is positioned in a plating chamber 21 of a vacuum sputtering machine 20. The plating chamber 21 is fixed with a target 23 therein. The plating chamber is internally heated from about 100° C. to about 400° C. Argon (Ar) can be used as a working gas and be injected into the chamber 21 at a flow rate of about 300 sccm to about 400 sccm. Oxygen (O₂) is used as reaction gas and injected into the chamber at a flow rate of about 50 sccm to about 75 sccm. Power of about 2.5 kw to about 3.5 kw is applied to the target 23 fixed in the plating chamber 21, and the substrate 11 may have a voltage of about −100 V to about −200 V to deposit the electrochromic layer 13 on the first conductive layer 12 of the substrate 11. Depositing of the electrochromic layer 13 may take about 30 minutes to 60 minutes. The resulting electrochromic layer 13 may have a thickness of about 500 nm to 800 nm.

In this exemplary embodiment, the target 23 is made of W doped with A metal, wherein the A metal is selected from one or more of Mo, Ni, Ti. The process of manufacturing the target 23 may include the following steps: mixing W and A metal with binders to form a mixture. The A metal has an atomic percentage in a range from about 5% to 15%, while the remaining percentage is made of W. The mixture is pressed into a blank. The blank is sintered in the furnace at a temperature from about 1700° C. to about 2000° C. for about 1.5 hours to about 3 hours. During the sintering process, the binders are removed from the powders and the individual metal powders bond together as the material diffusion occurs to remove most of the pores left by the removal of the binders.

After the electrochromic layer 13 is formed on the first conductive layer 12, the ion conductor layer 14, the ion storage layer 15, the second conductive layer 16 are located on the electrochromic layer 13 in that order by conventional techniques.

When a voltage of about 2.1 V to about 2.8 V is applied to the first conductive layer 12 and the second conductive layer 16, lithium ions of the ion conductor layer 14 enter the electrochromic layer 13. Consequently, some of the hexavalent W will be reduced to five valence electronics. Thus the electrochromic layer 13 will change from achromatic to blue.

The following experimental examples are provided.

### Example I

The vacuum sputtering machine 20 is a medium frequency magnetron sputtering device (model No. SM-1100H) manufactured by South Innovative Vacuum Technology Co., Ltd. located in Shenzhen, China. The substrate 11 is made of stainless steel. The A metal of the target 23 is Mo and Ti. The Mo metal has an atomic percentage of 5% and the Ti has an atomic percentage of 5%. The remaining composition is W powder. The mixture is pressed into a blank. The blank is sintered at a temperature of about 1800° C. in the furnace for about 2 hours. Ar is injected into the chamber at a rate of about 400 sccm. The substrate 11 is biased a −300V voltage. Plasma cleaning the substrate 11 may take about 10 minutes. The electrochromic layer 13 is vacuum sputtered on the substrate 11. The target 23 is applied at a power of about 4 KW. Ar is injected into the chamber 21 at a flow rate of about 300 sccm. O₂ is injected into the chamber at a flow rate of about 60 sccm, and the negative bias voltage may be about −100 V. The temperature is about 250° C. Depositing of the electrochromic layer 13 may take about 60 minutes.

The coated article 10 achieved from the first exemplary embodiment has an electrochromic layer 13 with an average thickness of about 640 nm. When the first conductive layer 12 and the second conductive layer 16 is applied at a voltage in a range from about 2.4 V to about 2.6 V, the color of the electrochromic layer 13 changes from achromatic to blue.

### Example II

The vacuum sputtering machine 20 is a medium frequency magnetron sputtering device (model No. SM-1100H) manufactured by South Innovative Vacuum Technology Co., Ltd. located in Shenzhen, China. The substrate 11 is made of aluminum alloy. The A metal of the target 23 is Mo, Nb and Ti. The Mo metal has an atomic percentage of 5%, the Nb metal has an atomic percentage of 1%, and the Ti has an atomic percentage of 3%. The remaining is W powder. The mixture is pressed into a blank. The blank is sintered at a temperature of about 1850° C. in the furnace for about 1.5 hours. Ar is injected into the chamber at a flow rate of about 400 sccm. The substrate 11 is biased with −300V negative bias voltage. Plasma cleaning the substrate 11 may take about 10 minutes. The electrochromic layer 13 is vacuum sputtered on the substrate 11. The target 23 is applied at a power of about 3.5 KW. Ar is injected into the chamber 21 at a flow rate of about 300 sccm. O₂ is injected into the chamber at a flow rate of about 50 sccm, and the negative bias voltage may be about −150 V. The temperature is about 200° C. Depositing of the electrochromic layer 13 may take about 60 minutes.

The coated article 10 achieved from the first exemplary embodiment has an electrochromic layer 13 with about an average thickness of 655 nm. When the first conductive layer 12 and the second conductive layer 16 is applied at a voltage in a range from about 2.3V to about 2.5V, the color of the electrochromic layer 13 changes from achromatic to blue.

### Example III

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Mo, Nb and Ti. The Mo metal has an atomic percentage of 5%, the Nb metal has an atomic percentage of 2%, and the Ti has an atomic percentage of 6%. The remaining is W powder. The mixture is pressed into a blank. The blank is sintered at a temperature of about 1900° C. in the furnace for about 2 hours. Ar is injected into the chamber at a flow rate of about 400 sccm. The substrate 11 is biased with −300V negative bias voltage. Plasma cleaning the substrate 11 may take about 20 minutes. The electrochromic layer 13 is vacuum sputtered on the substrate 11. The target 23 is applied at a power of about 4 KW. Ar is injected into the chamber 21 at a flow rate of about 300 sccm. O₂ is injected into the chamber at a flow rate of about 65 sccm, and the negative bias voltage may be about −120 V. The temperature is about 250° C. Depositing of the electrochromic layer 13 may take about 60 minutes.

The coated article 10 achieved from the first exemplary embodiment has an electrochromic layer 13 with about an average thickness of 590 nm. When the first conductive layer 12 and the second conductive layer 16 is applied at a voltage in a range from about 2.1V to about 2.4V, the color of the electrochromic layer 13 changes from achromatic to blue.

### Example IV

The vacuum sputtering machine 20 is a medium frequency magnetron sputtering device (model No. SM-1100H) manufactured by South Innovative Vacuum Technology Co., Ltd. located in Shenzhen, China. The substrate 11 is made of stainless steel. The A metal of the target 23 is Mo, Nb and Ti. The Mo metal has an atomic percentage of 3%, the Nb metal has an atomic percentage of 3%, and the Ti has an atomic percentage of 3%. The remaining is W powder. The mixture is pressed into a blank. The blank is sintered at a temperature of about 1950° C. in the furnace for about 1.5 hours. Ar is injected into the chamber at a flow rate of about 400 sccm. The substrate 11 is biased with −300V negative bias voltage. Plasma cleaning the substrate 11 may take about 10 minutes. The electrochromic layer 13 is vacuum sputtered on the substrate 11. The target 23 is applied at a power of about 4.5 KW. Ar is injected into the chamber 21 at a flow rate of about 300 sccm. O₂ is injected into the chamber at a flow rate of about 60 sccm, and the negative bias voltage may be about −150 V. The temperature is about 200° C. Depositing of the electrochromic layer 13 may take about 45 minutes.

The coated article 10 achieved from the first exemplary embodiment has an electrochromic layer 13 with about an average thickness of 590 nm. When the first conductive layer 12 and the second conductive layer 16 is applied at a voltage in a range from about 2.3V to about 2.5V, the color of the electrochromic layer 13 changes from achromatic to blue.

### Example V

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Mo and Nb. The Mo metal has an atomic percentage of 5%, and the Nb metal has an atomic percentage of 3%. The remaining is W powder. The mixture is pressed into a blank. The blank is sintered at a temperature of about 1950° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 4 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with about an average thickness of 565 nm. When the first conductive layer 12 and the second conductive layer 16 is applied at a voltage in a range from about 2.5V to about 2.8V, the color of the electrochromic layer 13 changes from achromatic to blue.

### Example VI

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Mo. The Mo metal has an atomic percentage of 15%. The remaining is W powder. The mixture is pressed into a blank. The blank is sintered at a temperature of about 1900° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 4 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with about an average thickness of 570 nm. When the first conductive layer 12 and the second conductive layer 16 is applied at a voltage in a range from about 2.3V to about 2.6V, the color of the electrochromic layer 13 changes from achromatic to blue.

### Example VII

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Nb. The Nb metal has an atomic percentage of 5%. The remaining is W powder. The mixture is pressed into a blank. The blank is sintered at a temperature of about 1800° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 3.5 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with about an average thickness of 540 nm. When the first conductive layer 12 and the second conductive layer 16 is applied at a voltage in a range from about 2.4V to about 2.7V, the color of the electrochromic layer 13 changes from achromatic to blue.

### Example VIII

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Nb. The Nb metal has an atomic percentage of 15%. The remaining is W powder. The mixture is pressed into a blank. The blank is sintered at a temperature of about 1950° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 4.5 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with about an average thickness of 555 nm. When the first conductive layer 12 and the second conductive layer 16 is applied at a voltage in a range from about 2.3V to about 2.5V, the color of the electrochromic layer 13 changes from achromatic to blue.

### Example IX

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Ti. The Ti metal has an atomic percentage of 5%. The remaining is W powder. The mixture is pressed into a blank. The blank is sintered at a temperature of about 1700° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 3 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with about an average thickness of 530 nm. When the first conductive layer 12 and the second conductive layer 16 is applied at a voltage in a range from about 2.5V to about 2.8V, the color of the electrochromic layer 13 changes from achromatic to blue.

### Example X

The vacuum sputtering machine 20 is a medium frequency magnetron sputtering device (model No. SM-1100H) manufactured by South Innovative Vacuum Technology Co., Ltd. located in Shenzhen, China. The substrate 11 is made of glass. The A metal of the target 23 is Ti. The Ti metal has an atomic percentage of 15%. The remaining is W powder. The mixture is pressed into a blank. The blank is sintered at a temperature of about 1800° C. in the furnace for about 2 hours. Ar is injected into the chamber at a flow rate of about 400 sccm. The substrate 11 is biased with −300V negative bias voltage. Plasma cleaning the substrate 11 may take about 60 minutes. The electrochromic layer 13 is vacuum sputtered on the substrate 11. The target 23 is applied at a power of about 3.5 KW. Ar is injected into the chamber 21 at a flow rate of about 300 sccm. O₂ is injected into the chamber at a flow rate of about 65 sccm, and the negative bias voltage may be about −120 V. The temperature is about 150° C. Depositing of the electrochromic layer 13 may take about 60 minutes.

The coated article 10 achieved from the first exemplary embodiment has an electrochromic layer 13 with an average thickness of about 520 nm. When the first conductive layer 12 and the second conductive layer 16 are applied at a voltage in a range from about 2.3 V to about 2.7 V, the color of the electrochromic layer 13 will change from achromatic to blue.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article comprising an electrochromic layer, the electrochromic layer made of tungsten trioxide doped with A metal, wherein A may be selected from a group consisting of one or more of molybdenum, niobium, and titanium.

2. The coated article as claimed in claim 1, wherein the A metal has an atomic percentage in a range from about 4% to 12% in the electrochromic layer.

3. The coated article as claimed in claim 1, wherein the electrochromic layer has a thickness of about 500 nm to about 800 nm.

4. The coated article as claimed in claim 1, wherein the coated article includes a substrate, a first conductive layer is formed on the substrate, and the electrochromic layer is formed on the first conductive layer.

5. The coated article as claimed in claim 4, wherein the coated article includes an ion conductor layer, an ion storage layer and a second conductive layer, the ion conductor layer, the ion storage layer and the second conductive layer are deposited on the first conductive layer in that order.

6. A method for making a coated article, comprising:
providing a substrate; and
forming an electrochromic layer on the substrate by vacuum sputtering deposition, the electrochromic layer made of tungsten trioxide doped with A metal, wherein A may be selected from a group consisting of one or more of molybdenum, niobium, and titanium.

7. The method as claimed in claim 6, wherein the A metal has an atomic percentage in a range from about 4% to 12% in the electrochromic layer.

8. The method as claimed in claim 6, wherein t the electrochromic layer has a thickness of about 500 nm to about 800 nm.

9. The method as claimed in claim 10, wherein vacuum sputtering the electrochromic layer uses a target made of Wu doped with A metal, wherein the A metal is selected from one or more of Mo, Ni, Ti, Argon is injected at a flow rate of about 300 to about 400 sccm, Oxygen is injected at a flow rate of about 50 sccm to about 75 sccm, power of about 2.5 kw to about 3.5 kw is applied to the target, and the substrate 11 is biased with negative bias voltage of about −100 V to about −200 V, and depositing of the electrochromic layer 13 takes about 30-60 minutes.

10. The method as claimed in claim 9, wherein the substrate is made of metal, glass or plastic.

11. The method as claimed in claim 6, further comprising a step of pre-treating the substrate before forming the electrochromic layer.

12. The method as claimed in claim 11, wherein the pre-treating process comprising ultrasonic cleaning the substrate and plasma cleaning the substrate.
